(19) United States
(12) Patent Application Publication
(10) Pub. No.: US 2026/0130247 A1
(43) Pub. Date: May 7, 2026

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: DAEYEUN CHOI, Suwon-si (KR); TAE-HO KO, Suwon-si (KR); UN-BYOUNG KANG, Suwon-si (KR); SEOKBONG PARK, Suwon-si (KR)

(21) Appl. No.: 19/201,429

(22) Filed: May 7, 2025

(30) Foreign Application Priority Data
Nov. 1, 2024 (KR) 10-2024-0153610

(51) Int. Cl. H01L 23/498; H01L 21/48; H01L 21/56; H01L 21/683; H01L 23/00; H01L 23/538; H01L 25/18; H10B 80/00; H10D 80/30

(52) U.S. Cl. CPC H10W 70/65; H10P 72/74; H10W 70/093; H10W 70/66; H10W 74/016; H10W 90/00; H10B 80/00; H10D 80/30; H10W 70/611; H10W 74/15; H10W 90/401; H10W 90/722; H10W 90/724; H10W 90/732; H10W 90/734

(57) ABSTRACT

A semiconductor package fabrication method includes attaching a first surface of a via structure having an opening to a surface of an adhesive member, forming conductive connectors and a bridge chip on the surface of the adhesive member and in the opening, removing the adhesive member, forming a first redistribution substrate on the first surface of the via structure, mounting chip structures on the first redistribution substrate, and forming a second redistribution substrate on a second surface of the via structure. The bridge chip has a first surface and an opposite second surface. The first surface of the bridge chip and the first surface of the via structure may be located at respective different levels.

### CROSS-REFERENCE TO RELATED APPLICATION

This application claims priority under 35 U.S.C § 119 to Korean Patent Application No. 10-2024-0153610 filed on Nov. 1, 2024 in the Korean Intellectual Property Office, the disclosure of which is hereby incorporated by reference in its entirety.

### BACKGROUND

The present inventive concepts relate to a semiconductor package, and more particularly, to a semiconductor package including a redistribution substrate and a method of fabricating the same.

With the development of the electronic industry, electronic products have increasing demands for high performance, high speed, and compact size. To meet the trend, there has recently been developed a packaging technology in which a plurality of semiconductor chips are mounted in a single package.

A semiconductor package is provided to implement an integrated circuit chip to qualify for use in electronic products. Typically, in the semiconductor package, a semiconductor chip is mounted on a printed circuit board (PCB) and bonding wires or bumps are used to electrically connect the semiconductor chip to the printed circuit board. With the recent development of the electronic industry, the semiconductor package is variously developed to reach the goal of compact size, small weight, and/or low manufacturing cost. In addition, many kinds of semiconductor packages show up with the expansion of their application field such as high-capacity mass storage devices.

### SUMMARY

Some embodiments of the present inventive concepts provide a semiconductor package with improved reliability and electrical properties and a method of fabricating the same.

An object of the present inventive concepts is not limited to the mentioned above, and other objects which have not been mentioned above will be clearly understood to those skilled in the art from the following description.

According to some embodiments of the present inventive concepts, a method of fabricating a semiconductor package may include attaching a first surface of a via structure to a surface of an adhesive member, the via structure having an opening; forming a plurality of conductive connectors and a bridge chip on the surface of the adhesive member and in the opening of the via structure; removing the adhesive member; forming a first redistribution substrate on the first surface of the via structure; mounting a plurality of chip structures on the first redistribution substrate; and forming a second redistribution substrate on an opposite second surface of the via structure. The bridge chip may have a first surface and an opposite second surface. The first surface of the bridge chip and the first surface of the via structure may be located at respective different levels.

According to some embodiments of the present inventive concepts, a method of fabricating a semiconductor package may include attaching a first surface of a via structure to a surface of an adhesive member, the via structure having an opening; forming a plurality of conductive connectors and a bridge chip on the surface of the adhesive member and in the opening of the via structure; forming a first carrier substrate on an opposite second surface of the via structure; removing the adhesive member; forming a first redistribution substrate on the first surface of the via structure; mounting a plurality of chip structures on the first redistribution substrate; forming on the first redistribution substrate a mold layer that covers the plurality of chip structures; removing the first carrier substrate; forming a second carrier substrate on the mold layer; and forming a second redistribution substrate on the second surface of the via structure. The bridge chip may have a first surface and an opposite second surface. The first surface of the bridge chip and the first surface of the via structure may be located at respective different levels.

According to some embodiments of the present inventive concepts, a method of manufacturing a semiconductor package includes attaching a first surface of a via structure to a surface of an adhesive member, wherein the via structure comprises a base layer, a plurality of conductive posts extending through the base layer, and an opening; forming a plurality of conductive connectors and a bridge chip on the surface of the adhesive member and in the opening of the via structure; forming a bridge mold layer on the surface of the adhesive member and in the opening of the via structure, the bridge mold layer covering the plurality of conductive connectors and the bridge chip; removing the adhesive member; forming a first redistribution substrate on the first surface of the via structure; mounting a plurality of chip structures on the first redistribution substrate; and forming a second redistribution substrate on an opposite second surface of the via structure.

### BRIEF DESCRIPTION OF DRAWINGS

FIG. 1 illustrates a plan view showing a semiconductor package according to some embodiments of the present inventive concepts.

FIG. 2A illustrates a cross-sectional view taken along line A-A′ of FIG. 1.

FIG. 2B illustrates a plan view showing a via structure according to some embodiments of the present inventive concepts.

FIG. 2C illustrates an enlarged view showing section C of FIG. 2A.

FIG. 2D illustrates an enlarged view showing section D of FIG. 2A.

FIGS. 3 to 14 illustrate cross-sectional views taken along line A-A′ of FIG. 1, showing a method of fabricating a semiconductor package according to some embodiments of the present inventive concepts.

FIG. 15 illustrates a cross-sectional view showing a semiconductor package according to some embodiments of the present inventive concepts.

### DETAILED DESCRIPTION OF EMBODIMENTS

The following will now describe in detail some embodiments of the present inventive concepts with reference to the accompanying drawings.

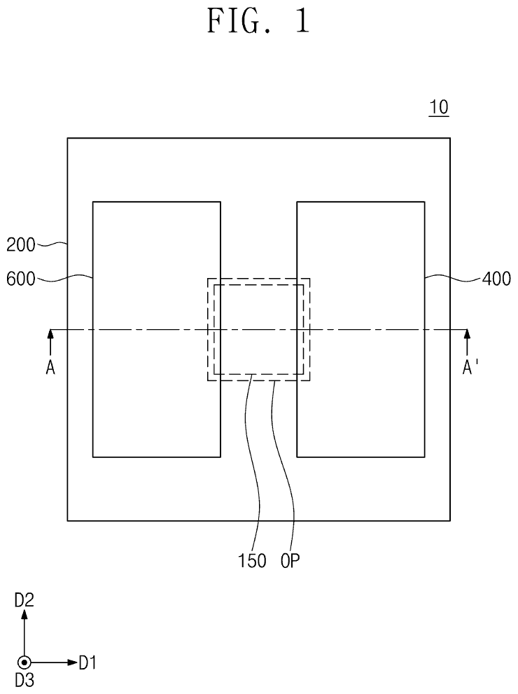

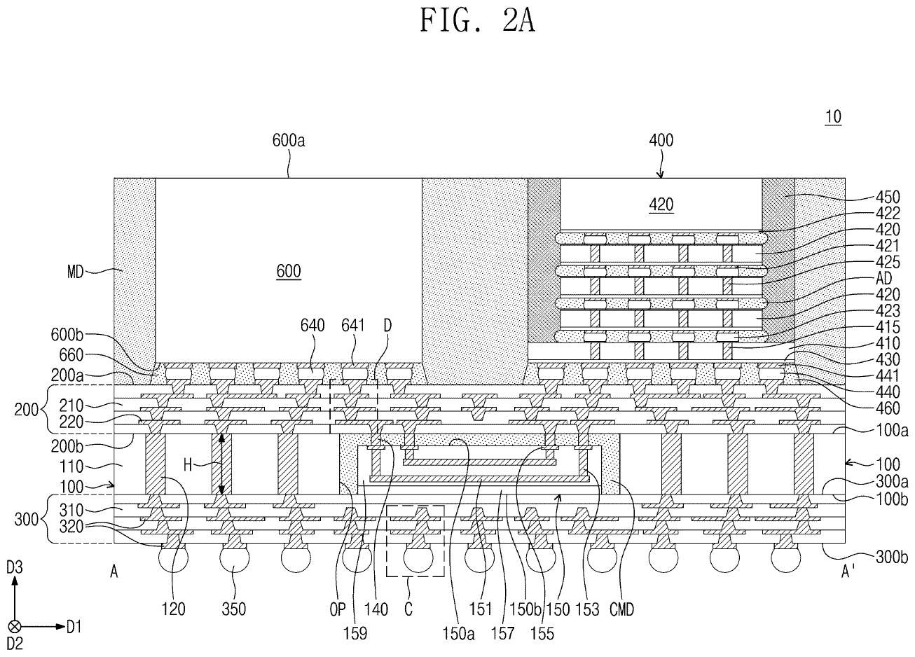

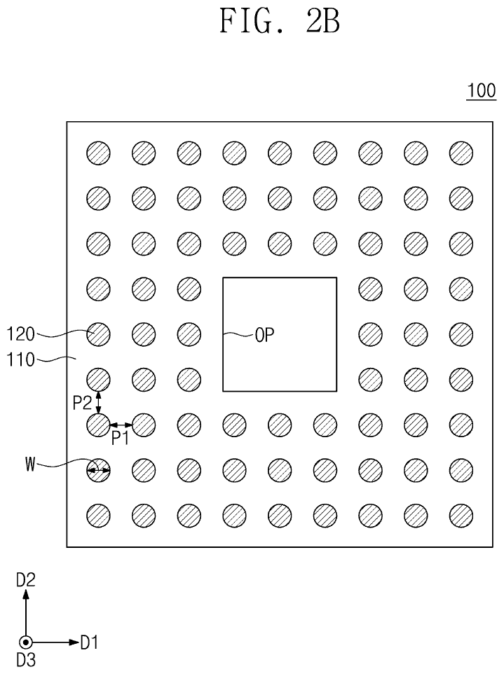

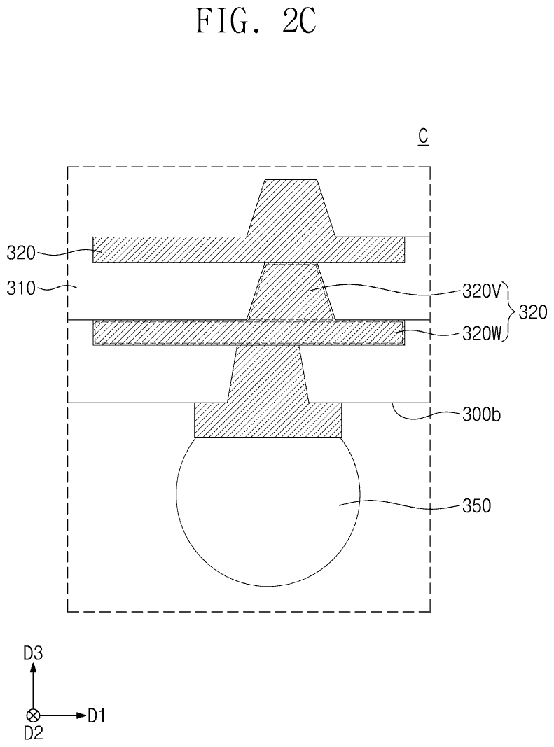

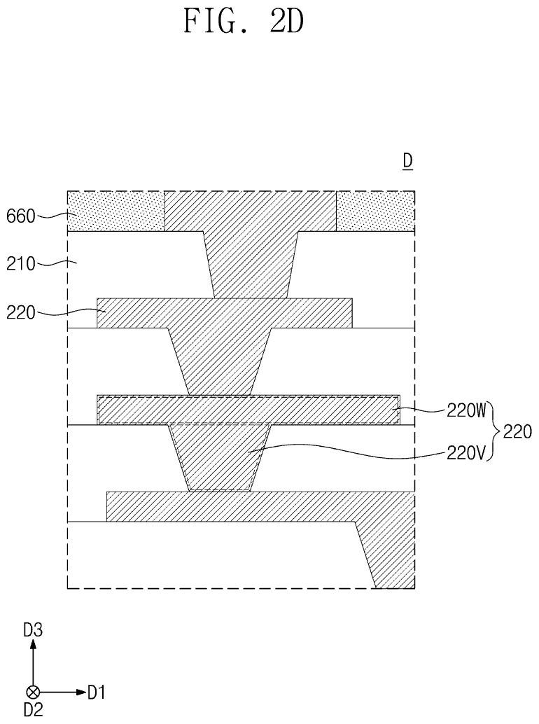

FIG. 1 illustrates a plan view showing a semiconductor package according to some embodiments of the present inventive concepts. FIG. 2A illustrates a cross-sectional view taken along line A-A′ of FIG. 1. FIG. 2B illustrates a plan view showing a via structure according to some embodiments of the present inventive concepts. FIG. 2C illustrates an enlarged view showing section C of FIG. 2A. FIG. 2D illustrates an enlarged view showing section D of FIG. 2A.

Referring to FIGS. 1 and 2A to 2D, a semiconductor package 10 according to some embodiments of the present inventive concepts may include a first redistribution substrate 200, a second redistribution substrate 300, a via structure 100, a bridge chip 150, and chip structures 400 and 600. The chip structures 400 and 600 may include, for example, a unit chip package 400 and a base chip 600. The second redistribution substrate 300 may have a first surface 300a and a second surface 300b that are opposite to each other in a third direction D3. In the description of FIGS. 1 and 2A to 2D, a first direction D1 and a second direction D2 may be directions that are parallel to the first surface 300a of the second redistribution substrate 300 and are crossed (i.e., transverse) to each other. The third direction D3 may be perpendicular to the first surface 300a of the second redistribution substrate 300. The third direction D3 may be called a vertical direction. For example, the first, second, and third directions D1, D2, and D3 may intersect each other.

The unit chip package 400 and the base chip 600 may be spaced apart from each other in a horizontal direction D1 and D2. For example, the unit chip package 400 and the base chip 600 may be spaced apart from each other in the first direction D1. The unit chip package 400 and the base chip 600 may have a chiplet structure. The chiplet may refer to any device obtained by dividing an existing chip based on its functions into chips and then connecting these chips using an interconnection structure.

The second redistribution substrate 300 may include a plurality of second redistribution dielectric layers 310 stacked in the vertical direction D3, second redistribution patterns 320, and redistribution connection terminals 350.

The second redistribution dielectric layers 310 may include an organic material, such as a photo-imageable dielectric (PID). The photo-imageable dielectric may be a polymer. The photo-imageable dielectric may include, for example, one or more of the following: photosensitive polyimide, polybenzoxazole, phenolic polymers, and benzocyclobutene polymers. FIG. 2A shows a boundary between the second redistribution dielectric layers 310, but the present inventive concepts are not limited thereto. According to some embodiments, an indistinct interface may be present between neighboring second redistribution dielectric layers 310.

The second redistribution pattern 320 may be disposed in the second redistribution dielectric layers 310. The second redistribution pattern 320 may be provided in plural. As illustrated in FIG. 2C, each of the second redistribution patterns 320 may include a second wire part 320W and a second via part 320V that are integrally connected to each other. The second wire part 320W may be a pattern for horizontal connection in the second redistribution substrate 300. The second via part 320V may be a portion for vertical connection of the second redistribution patterns 320 in the second redistribution dielectric layers 310. The second via part 320V and the second wire part 320W may be connected to each other without any interface. The second wire part 320W may have a major axis that extends in a direction parallel to the first surface 300a of the second redistribution substrate 300. The second wire part 320W may have a width greater than that of the second via part 320V. The second via part 320V may be disposed on the second wire part 320W. The second via part 320V may have a shape that protrudes toward the first surface 300a of the second redistribution substrate 300. An uppermost portion of the second via part 320V may have a width less than that of a lowermost portion of the second via part 320V. The width of the second via part 320V may decrease in a direction from the second surface 300b toward the first surface 300a of the second redistribution substrate 300. The second redistribution pattern 320 may include a conductive material, for example, one or more of the following: copper (Cu), tungsten (W), and titanium (Ti).

Lowermost ones of the second redistribution patterns 320 may be correspondingly connected to the redistribution connection terminals 350. The redistribution connection terminals 350 may be an alloy that includes one or more of the following: tin (Sn), silver (Ag), copper (Cu), nickel (Ni), bismuth (Bi), indium (In), antimony (Sb), and cerium (Ce).

The via structure 100 may be disposed on the first surface 300a of the second redistribution substrate 300. The via structure 100 may have a first surface 100a and a second surface 100b that are opposite to each other in the vertical direction D3. The second surface 100b of the via structure 100 may be disposed adjacent to the first surface 300a of the second redistribution substrate 300. Referring to FIG. 2B, the via structure 100 may include an opening OP. According to some embodiments, differently from that shown, the via structure 100 may include a plurality of openings OP.

The via structure 100 may include a via base layer 110 and a plurality of conductive posts 120 that penetrate in the vertical direction D3 (i.e., extend) through the via base layer 110 (i.e., the direction D3 is a direction orthogonal to the first and second surfaces 100a, 100b of the via structure 100, and, depending on the orientation of the via structure, may be vertical). The conductive posts 120 may be spaced apart from each other in the first direction D1 and the second direction D2. The conductive posts 120 may have top surfaces coplanar with that of the via base layer 110. The conductive posts 120 may have bottom surfaces coplanar with that of the via base layer 110. When viewed in plan, each of the conductive posts 120 may have a circular shape. For example, when viewed in plan, each of the conductive posts 120 may have a diameter W of about 40 to 100 μm. A first distance P1 in the first direction D1 between the conductive posts 120 that neighbor each other in the first direction D1 may be about 0.8 to 1.2 times the diameter W of the conductive post 120. A second distance P2 in the second direction D2 between the conductive posts 120 that neighbor each other in the second direction D2 may be about 0.8 to 1.2 times the diameter W of the conductive post 120. For example, according to some embodiments, when the diameter W is about 100 μm, the first distance P1 and the second distance P2 may each be about 80 to 120 μm. According to some embodiments, when the diameter W is about 40 μm, the first distance P1 and the second distance P2 may each be about 32 to 48 μm.

The conductive posts 120 may each have a cylindrical shape that extends in the vertical direction D3. In each of the conductive posts 120, the diameter W at the bottom surface may be the same as the diameter W at the top surface. For example, each of the conductive posts 120 may maintain the same diameter W from the bottom surface to the top surface. Each of the conductive posts 120 may have a height H measured in the vertical direction D3. For example, the height H of each of the conductive posts 120 may be about 100 to 250 μm. A variation in the heights H of the conductive posts 120 may be less than about 10 μm. For example, a variation in the heights H of the conductive posts 120 may be less than about 2 μm. According to some embodiments, a variation in the heights H of the conductive posts 120 may be about 1 to 2 μm. In this description, a variation in the heights H may refer to a difference in height H between the conductive posts 120.

The via base layer 110 may include, for example, one or more of the following: silicon, glass, and organics. The organics may include, for example, one or more of the following: fiber glass epoxy, glass paper epoxy, Teflon™, resin coated copper (RCC), and ceramics. The conductive posts 120 may include a conductive material. The conductive posts 120 may include, for example, copper (Cu).

The bridge chip 150 may be disposed on the first surface 300a of the second redistribution substrate 300 and in the opening OP of the via structure 100. The bridge chip 150 may have a first surface 150a and a second surface 150b that are opposite to each other in the vertical direction D3. The second surface 150b of the bridge chip 150 may be adjacent to the first surface 300a of the second redistribution substrate 300. The second surface 150b of the bridge chip 150 may be coplanar with the second surface 100b of the via structure 100. Although not shown, the bridge chip 150 may further include an adhesive layer on a portion adjacent to the second surface 150b. The first surface 150a of the bridge chip 150 may be located at a level different from that of the first surface 100a of the via structure 100. According to some embodiments, the first surface 150a of the bridge chip 150 may be located at a level lower than that of the first surface 100a of the via structure 100. In the description of FIGS. 1 to 2D, the level may refer to a height measured in the vertical direction D3 from the first surface 300a of the second redistribution substrate 300.

The bridge chip 150 may include a bridge dielectric layer 159, a bridge base layer 157, bridge lines 151, bridge plugs 153, and bridge pads 155. The bridge base layer 157 may include a semiconductor substrate. For example, the bridge base layer 157 may be a semiconductor substrate, such as a semiconductor wafer. The bridge base layer 157 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG). The bridge base layer 157 may include, for example, one or more of the following: silicon (Si), germanium (Ge), silicon germanium (SiGe), gallium arsenic (GaAs), indium gallium arsenic (InGaAs), aluminum gallium arsenic (AlGaAs), and a mixture thereof.

The bridge lines 151 and the bridge plugs 153 may be disposed in the bridge dielectric layer 159. The bridge dielectric layer 159 may include a single layer or a plurality of layers. The bridge lines 151 and the bridge plugs 153 may be connected to corresponding bridge pads 155. The bridge dielectric layer 159 may include, for example, silicon oxide, silicon nitride, silicon oxynitride, or dielectric polymer. The bridge lines 151, the bridge plugs 153, and the bridge pads 155 may include a conductive material. For example, the bridge lines 151, the bridge plugs 153, and the bridge pads 155 may include copper (Cu) or aluminum (Al).

Conductive connectors 140 may be disposed on the bridge chip 150. The conductive connectors 140 may be disposed on the first surface 150a of the bridge chip 150. The conductive connectors 140 may be connected to corresponding bridge pads 155. The conductive connectors 140 may be in contact with corresponding bridge pads 155. The conductive connectors 140 may be interposed between the bridge chip 150 and the first redistribution substrate 200 which will be discussed below.

A bridge mold layer CMD may be disposed on the first surface 300a of the second redistribution substrate 300 and in the opening OP of the via structure 100. The bridge mold layer CMD may cover the bridge chip 150. A top surface of the bridge mold layer CMD may be coplanar with the first surface 100a of the via structure 100. The bridge mold layer CMD may include a dielectric material, for example, an epoxy molding compound (EMC).

The first redistribution substrate 200 may be disposed on the via structure 100 and the bridge mold layer CMD. The first redistribution substrate 200 may be disposed on the first surface 100a of the via structure 100. The first redistribution substrate 200 may have a first surface 200a and a second surface 200b that are opposite to each other in the vertical direction D3. The second surface 200b of the first redistribution substrate 200 may be adjacent to the first surface 100a of the via structure 100. The second surface 200b of the first redistribution substrate 200 may be adjacent to the top surface of the bridge mold layer CMD. The first redistribution substrate 200 may include a plurality of first redistribution dielectric layers 210 and a plurality of first redistribution patterns 220 that are stacked in the vertical direction D3.

The first redistribution dielectric layers 210 may include an organic material, such as a photo-imageable dielectric (PID). The photo-imageable dielectric may be a polymer. The photo-imageable dielectric may include, for example, one or more of the following: photosensitive polyimide, polybenzoxazole, phenolic polymers, and benzocyclobutene polymers. FIG. 2A shows a boundary between the first redistribution dielectric layers 210, but the present inventive concepts are not limited thereto. According to some embodiments, an indistinct interface may be present between neighboring first redistribution dielectric layers 210.

The first redistribution pattern 220 may be disposed in the second redistribution dielectric layers 210. The first redistribution pattern 220 may be provided in plural. As illustrated in FIG. 2D, each of the first redistribution patterns 220 may include a first wire part 220W and a first via part 220V that are integrally connected to each other. The first wire part 220W may be a pattern for horizontal connection in the first redistribution substrate 200. The first via part 220V may be a portion for vertical connection of the first redistribution patterns 220 in the first redistribution dielectric layers 210. The first via part 220V and the first wire part 220W may be connected to each other without any interface. The first wire part 220W may have a major axis that extends in a direction parallel to the first surface 200a of the first redistribution substrate 200. The first wire part 220W may have a width greater than that of the first via part 220V. The first wire part 220W may be disposed on the first via part 220V. The first via part 220V may have a shape that protrudes toward the second surface 200b of the first redistribution substrate 200. An upper portion of the first via part 220V may have a width greater than that of a lowermost portion of the first via part 220V. The width of the first via part 220V may increase in a direction from the second surface 200b toward the first surface 200a of the first redistribution substrate 200. The first redistribution pattern 220 may include a conductive material, for example, one or more of the following: copper (Cu), tungsten (W), and titanium (Ti).

Some of lowermost ones of the first redistribution patterns 220 may be connected to corresponding conductive posts 120. The first redistribution substrate 200 and the second redistribution substrate 300 may be electrically connected through the conductive posts 120. For example, the via structure 100 may electrically connect the first redistribution substrate 200 through the conductive posts 120 to the second redistribution substrate 300.

Others of lowermost ones of the first redistribution patterns 220 may be connected to corresponding conductive connectors 140. The first redistribution substrate 200 may be electrically connected through the conductive connectors 140 to the bridge chip 150.

The chip structures 400 and 600 may be mounted on the first redistribution substrate 200. According to some embodiments, the base chip 600 and the unit chip package 400 may be disposed spaced apart in the first direction D1 from each other on the first redistribution substrate 200. The number and arrangement of the unit chip package 400 and the base chip 600 may be variously changed depending on design.

The unit chip package 400 may be a high bandwidth memory (HBM). The unit chip package 400 may include a lower semiconductor chip 410 and a plurality of semiconductor chips 420 that are stacked on the lower semiconductor chip 410. The plurality of semiconductor chips 420 may be disposed on a top surface of the lower semiconductor chip 410 and may be stacked along the vertical direction D3. FIG. 2A depicts by way of example a structure where four semiconductor chips 420 are stacked on the lower semiconductor chip 410, but the present inventive concepts are not limited thereto. The number of the semiconductor chips 420 may be multiple, which are stacked on the lower semiconductor chip 410 may be multiple.

The lower semiconductor chip 410 may include a lower circuit layer 430 adjacent to a bottom surface of a lower semiconductor substrate. The lower circuit layer 430 may include integrated circuits formed on the lower semiconductor substrate. Lower through electrodes 415 may be disposed to penetrate the lower semiconductor substrate. The lower through electrodes 415 may be horizontally spaced apart from each other in the lower semiconductor substrate. The lower through electrode 415 may be electrically connected to the lower circuit layer 430. The lower through electrodes 415 may include metal (e.g., copper, tungsten, titanium, or tantalum).

The plurality of semiconductor chips 420 may be sequentially stacked in the vertical direction D3 on the top surface of the lower semiconductor chip 410. Each of the plurality of semiconductor chips 420 may include a semiconductor substrate, a circuit layer 422, chip pads 421, bumps 423, and through electrodes 425. The through electrodes 425 may penetrate (i.e., extend through) the semiconductor substrate, and may be horizontally spaced apart from each other in the semiconductor substrate. The through electrodes 425 may be electrically connected to the circuit layer 422. An uppermost one of the plurality of semiconductor chips 420 may not include the through electrodes. The through electrodes 425 may include metal (e.g., copper, tungsten, titanium, or tantalum).

Among the plurality of semiconductor chips 420, the semiconductor chips 420 that are adjacent to each other in the vertical direction D3 may be electrically connected to each other through the bumps 423 disposed therebetween. A lowermost one of the plurality of semiconductor chips 420 and the lower semiconductor chip 410 may be electrically connected through the bumps 423 disposed therebetween. The bumps 423 may include a conductive material, and may have one or more of the following: solder-ball shapes, bump shapes, and pillar shapes.

The unit chip package 400 may further include nonconductive layers AD interposed between the lowermost semiconductor chip 420 and the lower semiconductor chip 410 and between the plurality of semiconductor chips 420. Each of the nonconductive layers AD may fill a space between the bumps 423 disposed between the semiconductor chips 420 that neighbor each other in the vertical direction D3. According to some embodiments, each of the nonconductive layers AD may include a protrusion that protrudes from a lateral surface of the semiconductor chip 420 adjacent thereto. The nonconductive layers AD may include a thermosetting resin, such as one or more of the following: bisphenol-type epoxy resin, novolac-type epoxy resin, phenolic resin, urea resin, melamine resin, unsaturated polyester resin, and resorcinol resin.

A mold layer 450 may be disposed on the lower semiconductor chip 410. The mold layer 450 may cover lateral surfaces of the plurality of semiconductor chips 420. The mold layers 450 may cover the protrusions that are lateral surfaces of the nonconductive layers AD. The mold layer 450 may extend from the top surface of the lower semiconductor chip 410 to a top surface of an uppermost one of the plurality of semiconductor chips 420. The mold layer 450 may expose the top surface of an uppermost one of the plurality of semiconductor chips 420. A top surface of the mold layer 450 may be coplanar with that of an uppermost one of the plurality of semiconductor chips 420. The mold layer 450 may include a dielectric material (e.g., an epoxy molding compound (EMC)).

The plurality of semiconductor chips 420 may be memory chips. The plurality of semiconductor chips 420 may be the same semiconductor chips, for example, the same memory chips. The lower semiconductor chip 410 may be a memory chip, a logic chip, an application processor (AP) chip, or a system-on-chip (SOC). The plurality of semiconductor chips 420 and the lower semiconductor chip 410 may be electrically connected to each other, and may constitute a high bandwidth memory (HBM) chip.

Lower chip pads 441 and lower connection terminals 440 may be disposed below the lower circuit layer 430 of the lower semiconductor chip 410. The lower connection terminals 440 may be correspondingly disposed on the lower chip pads 441. The lower connection terminals 440 may be connected to the first redistribution substrate 200. For example, the lower connection terminals 440 may be connected to uppermost ones of the first redistribution patterns 220 of the first redistribution substrate 200. The unit chip package 400 may be electrically connected through the lower connection terminals 440 to the first redistribution substrate 200. The lower connection terminals 440 may be an alloy that includes one or more of the following: tin (Sn), silver (Ag), copper (Cu), nickel (Ni), bismuth (Bi), indium (In), antimony (Sb), and cerium (Ce).

A chip underfill pattern 460 may be interposed between the unit chip package 400 and the first redistribution substrate 200. The chip underfill pattern 460 may fill a space between the lower connection terminals 440, and may cover the lower connection terminals 440. The chip underfill pattern 460 may include a dielectric polymer material, such as epoxy resin.

The base chip 600 may be, for example, one of a central processing unit (CPU), a graphic processing unit (GPU), and an application specific integrated circuit (ASIC).

The base chip 600 may have a first surface 600a and a second surface 600b that are opposite to each other in the vertical direction D3. Base chip pads 641 and base connection terminals 640 may be disposed on the second surface 600b of the base chip 600. The base connection terminals 640 may be correspondingly disposed on the base chip pads 641. The base connection terminals 640 may be connected to the first redistribution substrate 200. For example, the base connection terminals 640 may be connected to uppermost ones of the first redistribution patterns 220. The base chip 600 may be electrically connected through the base connection terminals 640 to the first redistribution substrate 200. The base connection terminals 640 may be an alloy that includes one or more of the following: tin (Sn), silver (Ag), copper (Cu), nickel (Ni), bismuth (Bi), indium (In), antimony (Sb), and cerium (Ce).

A base underfill pattern 660 may be interposed between the base chip 600 and the first redistribution substrate 200. The base underfill pattern 660 may fill a space between the base connection terminals 640, and may cover the base connection terminals 640. The base underfill pattern 660 may include a dielectric polymer material, such as epoxy resin.

The base chip 600 and the unit chip package 400 may be electrically connected through the first redistribution substrate 200, the conductive connectors 140, and the bridge chip 150.

A mold layer MD may be disposed on the first redistribution substrate 200. The mold layer MD may extend from the first surface 200a of the first redistribution substrate 200 to the first surface 600a of the base chip 600. The mold layer MD may cover a lateral surface of the unit chip package 400, and may fill a space between the unit chip package 400 and the base chip 600. The mold layer MD may cover lateral surfaces of the base underfill pattern 660 and lateral surfaces of the chip underfill pattern 460. The mold layer MD may fill a space between the base underfill pattern 660 and the chip underfill pattern 460. The mold layer MD may include a dielectric material (e.g., an epoxy molding compound (EMC)).

According to some embodiments of the present inventive concepts, the semiconductor package 10 may utilize the via structure 100 where the conductive posts 120 are manufactured in advance. In contrast, when the conductive posts 120 are formed and utilized, an asymmetric interval may be provided between the conductive posts 120. Therefore, when a planarization process is performed in a subsequent procedure, there may be a difference in the degree of etching, and there may be an increased variation in the heights H of the conductive posts 120. In this sense, it may be difficult to achieve stable management of the heights H of the conductive posts 120. In addition, when a plating process is used to form the conductive posts 120, the conductive posts 120 may be formed to have thick upper portions, and thus there may occur failure where a photoresist is not removed.

According to the present inventive concepts, the via structure 100 may be utilized in which a symmetric interval is provided between the conductive posts 120. Thus, it may not be required to perform a planarization process on the conductive posts 120, and it may be possible to eliminate the risk of increased variation in the heights H of the conductive posts 120. It may also be possible to reduce difficulty of fabrication process. Additionally, there may be no occurrence of failure where a photoresist remains on the conductive posts 120. Furthermore, it may be possible to prevent the occurrence of wafer warpage. In conclusion, a semiconductor package may have improved reliability and improved electrical properties.

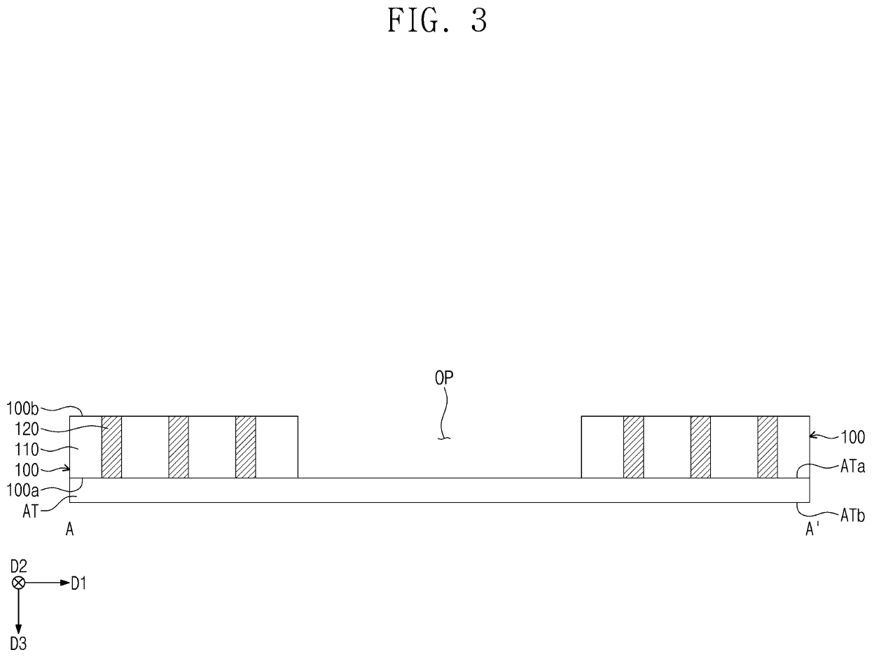

FIGS. 3 to 14 illustrate cross-sectional views taken along line A-A′ of FIG. 1, showing a method of fabricating a semiconductor package according to some embodiments of the present inventive concepts. For brevity of description, omission will be made to avoid repetition of explanation of the semiconductor package discussed with reference to FIGS. 1 and 2A to 2D.

Referring to FIG. 3, an adhesive member AT may be provided. The adhesive member AT may include, for example, a glue tape. The adhesive member AT may have a top surface ATa and a bottom surface ATb that are opposite to each other in a third direction D3. In FIGS. 3 to 14, the third direction D3 may be a direction perpendicular to and away from the bottom surface ATb of the adhesive member AT. A first direction D1 and a second direction D2 may be directions that are parallel to the top surface ATa of the adhesive member AT and are crossed (i.e., transverse) to each other. For example, the first, second, and third directions D1, D2, and D3 may intersect each other.

A via structure 100 may be attached to the top surface ATa of the adhesive member AT. For example, a first surface 100a of the via structure 100 may be attached to the top surface ATa of the adhesive member AT. The via structure 100 may have the first surface 100a and a second surface 100b that are opposite to each other in the third direction D3. The via structure 100 may include an opening OP. The via structure 100 may include a via base layer 110 and conductive posts 120. The via structure 100 may be manufactured in advance. The via structure 100 may be substantially the same as the via structure 100 discussed with reference to FIGS. 1, 2A, and 2B.

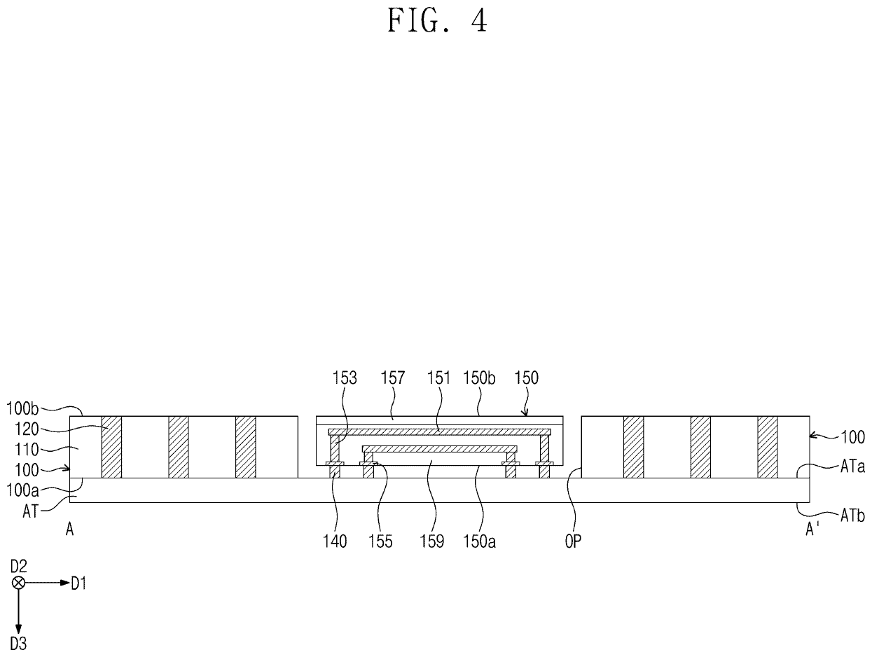

Referring to FIG. 4, conductive connectors 140 may be formed on the top surface ATa of the adhesive member AT and in the opening OP of the via structure 100. A bridge chip 150 may be formed on the conductive connectors 140. The bridge chip 150 may include a bridge dielectric layer 159, a bridge base layer 157, bridge lines 151, bridge plugs 153, and bridge pads 155. The bridge chip 150 may include substantially the same configuration as that of the bridge chip 150 discussed with reference to FIGS. 1 and 2A. The bridge chip 150 may have a first surface 150a and a second surface 150b that are opposite to each other in the third direction D3. According to some embodiments, the first surface 150a of the bridge chip 150 may be located at a level different from that of the first surface 100a of the via structure 100. The second surface 150b of the bridge chip 150 may be located at a level substantially the same as that of the second surface 100b of the via structure 100. In the description of FIGS. 3 to 14, the level may be a distance measured in a direction, opposite to the third direction D3, from the bottom surface ATb of the adhesive member AT.

The conductive connectors 140 and the bridge chip 150 may be formed horizontally spaced apart from the via structure 100. The conductive connectors 140 may be interposed between the adhesive member AT and the bridge chip 150. The conductive connectors 140 may be in contact with the top surface ATa of the adhesive member AT. The conductive connectors 140 may be in contact with the first surface 150a of the bridge chip 150.

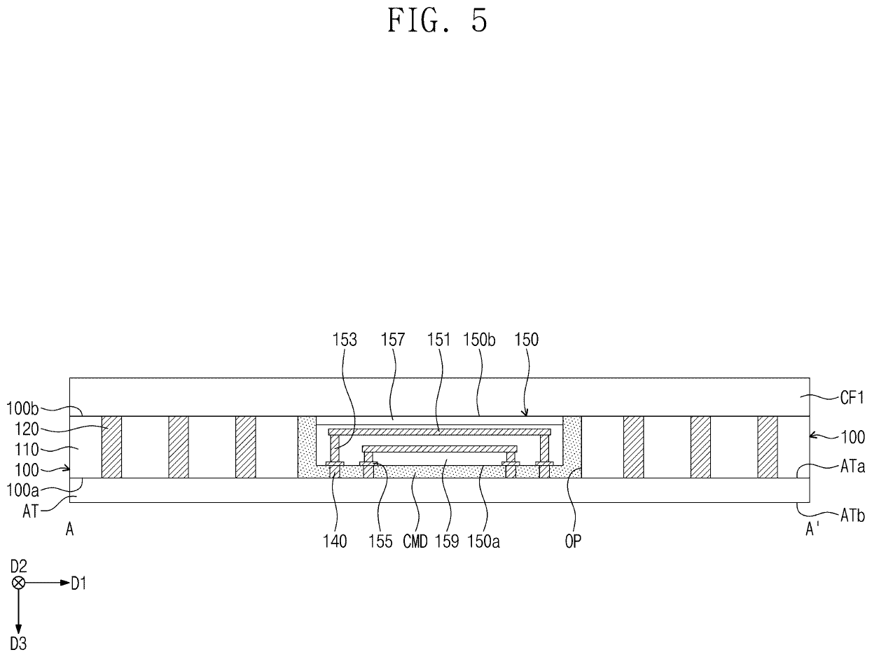

Referring to FIG. 5, a bridge mold layer CMD may be formed on the top surface ATa of the adhesive member AT and in the opening OP of the via structure 100. The bridge mold layer CMD may extend from the top surface ATa of the adhesive member AT to the second surface 150b of the bridge chip 150. The bridge mold layer CMD may fill between the conductive connectors 140 on the first surface 150a of the bridge chip 150. The bridge mold layer CMD may fill between the via structure 100 and the bridge chip 150.

A first carrier substrate CF1 may be formed on the second surface 100b of the via structure 100 and the second surface 150b of the bridge chip 150. The first carrier substrate CF1 may be in contact with the second surface 100b of the via structure 100 and the second surface 150b of the bridge chip 150.

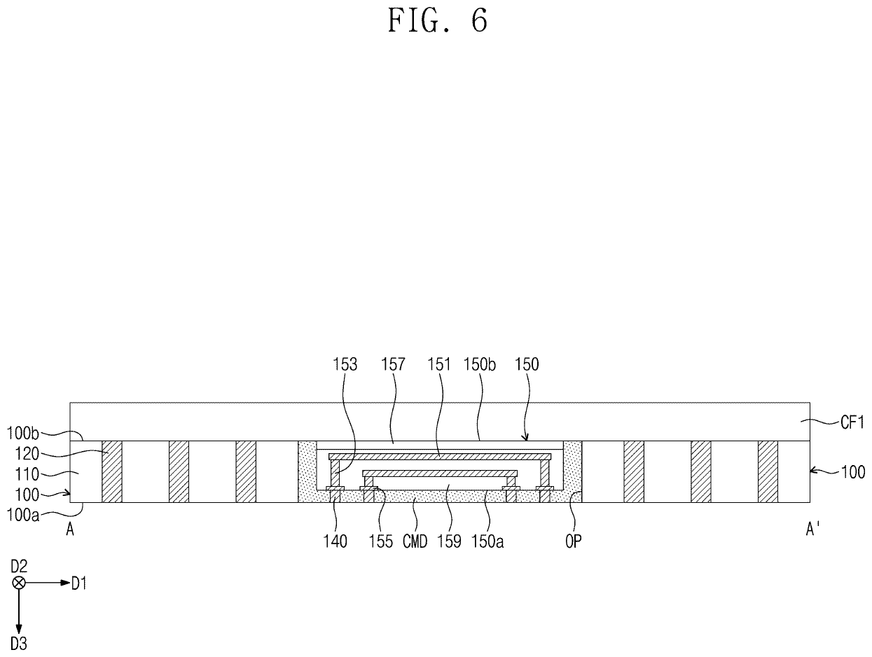

Referring to FIG. 6, the adhesive member AT may be removed. The removal of the adhesive member AT may expose the first surface 100a of the via structure 100. In addition, the conductive connectors 140 may be exposed.

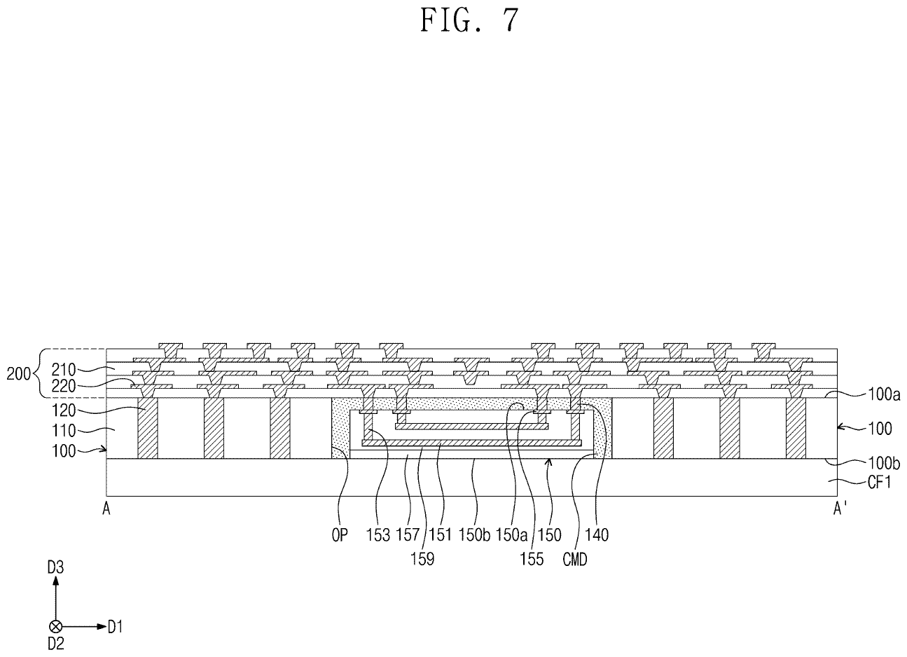

Referring to FIG. 7, the first carrier substrate CF1 may be overturned to allow the first surface 100a of the via structure 100 to face upwards. For example, a semiconductor package being fabricated may be turned upside down. Therefore, the first carrier substrate CF1 may be positioned at a lower location.

A first redistribution substrate 200 may be formed. The first redistribution substrate 200 may be formed on the first surface 100a of the via structure 100. The formation of the first redistribution substrate 200 may include, for example, forming a first redistribution dielectric layer 210, forming a plurality of holes (not shown) in the first redistribution dielectric layer 210, forming a seed layer (not shown) in the holes and performing an electroplating process in which the seed layer is used as an electrode to form a conductive layer (not shown), and patterning the conductive layer to form first redistribution patterns 220. The procedure discussed above may be repeated to form a plurality of first redistribution dielectric layers 210 and the first redistribution patterns 220 disposed in the plural layers. The first redistribution substrate 200 may include substantially the same configuration discussed with reference to FIG. 2D. The first redistribution patterns 220 may be formed connected to corresponding conductive posts 120 and corresponding conductive connectors 140.

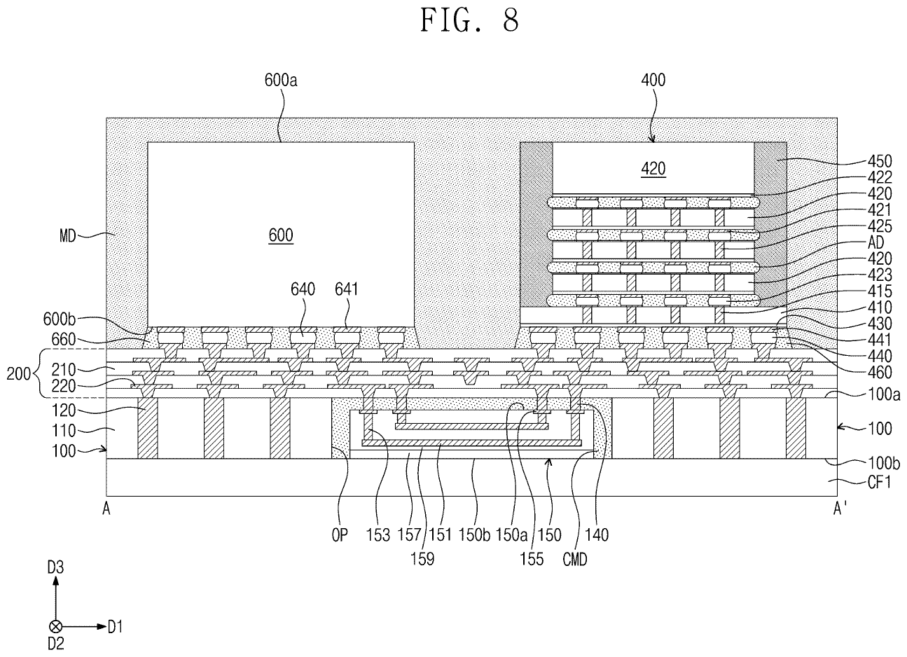

Referring to FIG. 8, chip structures 400 and 600 may be mounted on the first redistribution substrate 200. The chip structures 400 and 600 may include, for example, a base chip 600 and a unit chip package 400. The base chip 600 may have a first surface 600a and a second surface 600b that are opposite to each other in the third direction D3. The unit chip package 400 may include a lower semiconductor chip 410, a plurality of semiconductor chips 420, a lower circuit layer 430, nonconductive layers AD, lower through electrodes 415, and a mold layer 450. Each of the plurality of semiconductor chips 420 may include a semiconductor substrate, a circuit layer 422, chip pads 421, bumps 423, and through electrodes 425. The chip structures 400 and 600 may include substantially the same configurations as those of the unit chip package 400 and the base chip 600 discussed with reference to FIGS. 1 and 2A. The mounting of the base chip 600 may include forming base connection terminals 640 between the base chip pads 641 of the base chip 600 and their corresponding first redistribution patterns 220. The mounting of the unit chip package 400 may include forming lower connection terminals 440 between the lower chip pads 441 and their corresponding first redistribution patterns 220.

A base underfill pattern 660 may be formed between the first redistribution substrate 200 and the base chip 600. A chip underfill pattern 460 may be formed between the first redistribution substrate 200 and the unit chip package 400.

A mold layer MD may be formed on the first redistribution substrate 200. The mold layer MD may cover a lateral surface of the base underfill pattern 660, a lateral surface of the base chip 600, a lateral surface of the chip underfill pattern 460, and a lateral surface of the unit chip package 400. The mold layer MD may cover the first surface 600a of the base chip 600. The mold layer MD may cover an upside of the unit chip package 400.

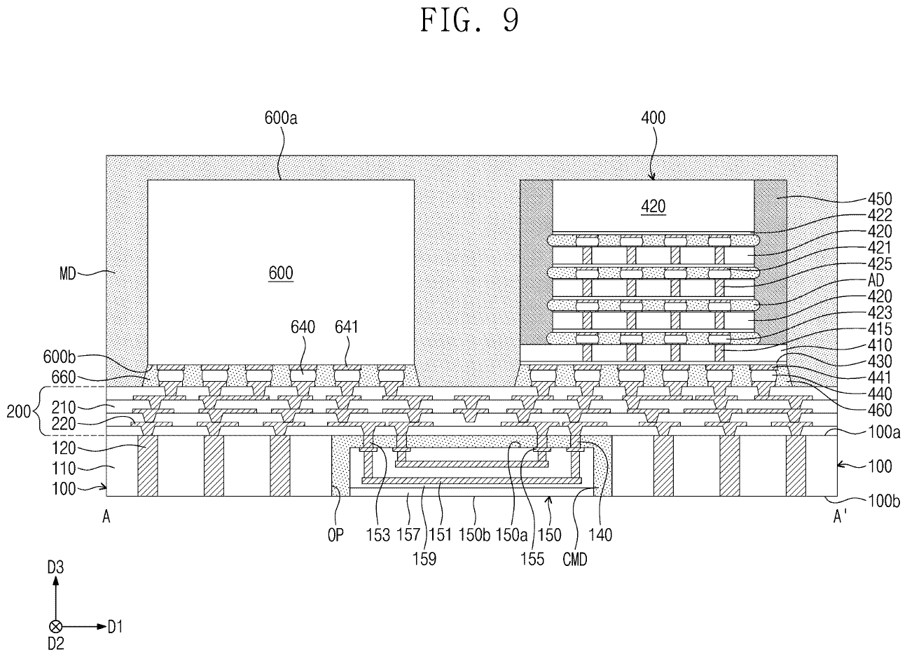

Referring to FIG. 9, a first carrier substrate CF1 may be removed. The removal of the first carrier substrate CF1 may expose the second surface 100b of the via structure 100 and the second surface 150b of the bridge chip 150.

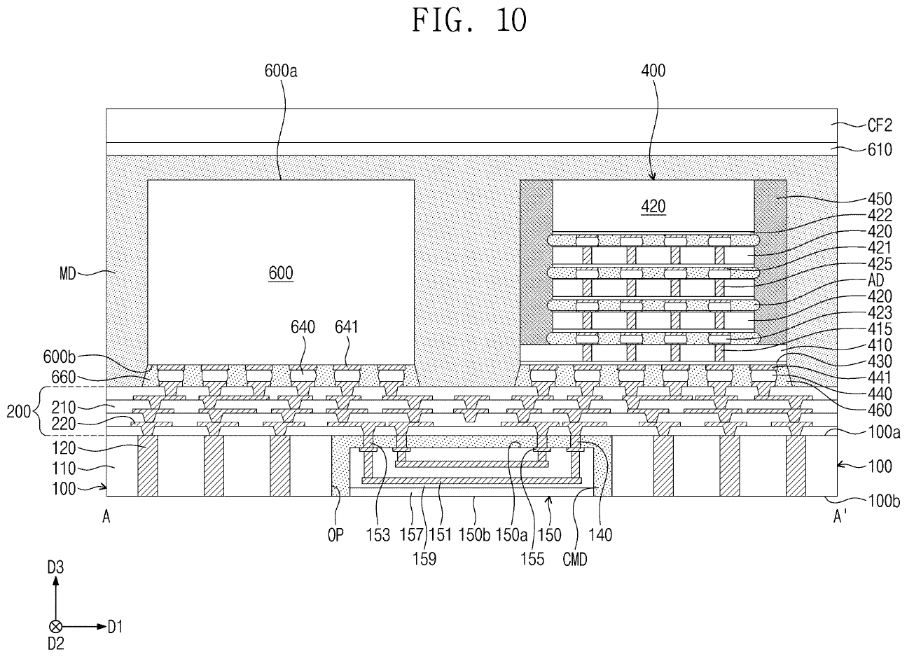

Referring to FIG. 10, a dielectric film 610 may be formed on the mold layer MD. A second carrier substrate CF2 may be formed on the dielectric film 610. The dielectric film 610 may be a layer that serves to achieve bonding and protecting.

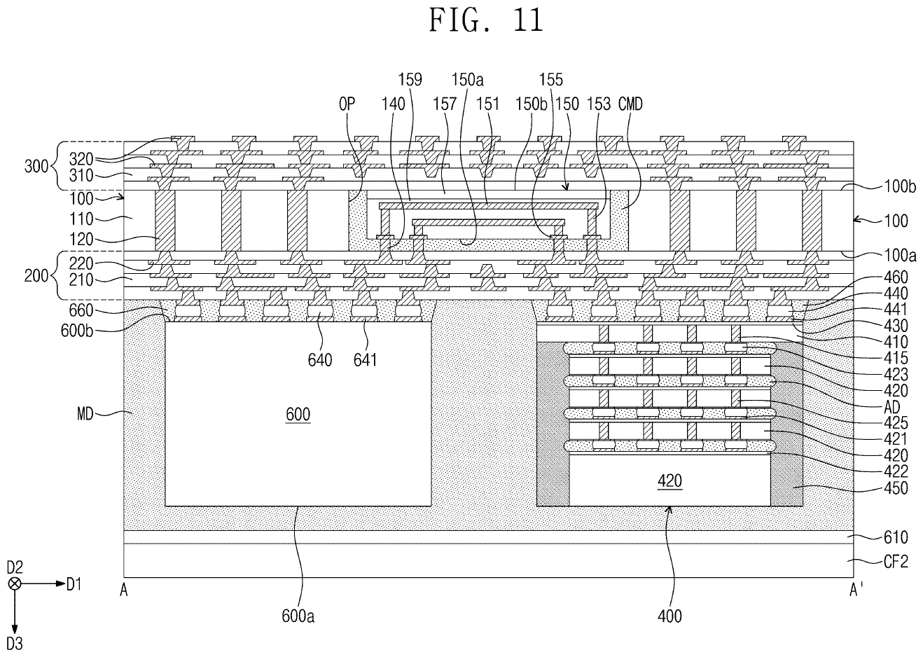

Referring to FIG. 11, the second carrier substrate CF2 may be overturned to allow the second surface 100b of the via structure 100 to face upwards. For example, a semiconductor package being fabricated may be turned upside down. Thus, the second carrier substrate CF2 may be positioned at a lower location.

A second redistribution substrate 300 may be formed. The second redistribution substrate 300 may be formed on the second surface 100b of the via structure 100 and the second surface 150b of the bridge chip 150. The formation of the second redistribution substrate 300 may include, for example, forming a second redistribution dielectric layer 310, forming a plurality of holes (not shown) in the second redistribution dielectric layer 310, forming a seed layer (not shown) in the holes and performing an electroplating process in which the seed layer is used as an electrode to form a conductive layer (not shown), and patterning the conductive layer to form second redistribution patterns 320. The procedure discussed above may be repeated to form a plurality of second redistribution dielectric layers 310 and the second redistribution patterns 320 disposed in the plural layers. The second redistribution substrate 300 may include substantially the same configuration as that discussed with reference to FIG. 2C. The second redistribution patterns 320 may be formed connected to corresponding conductive posts 120.

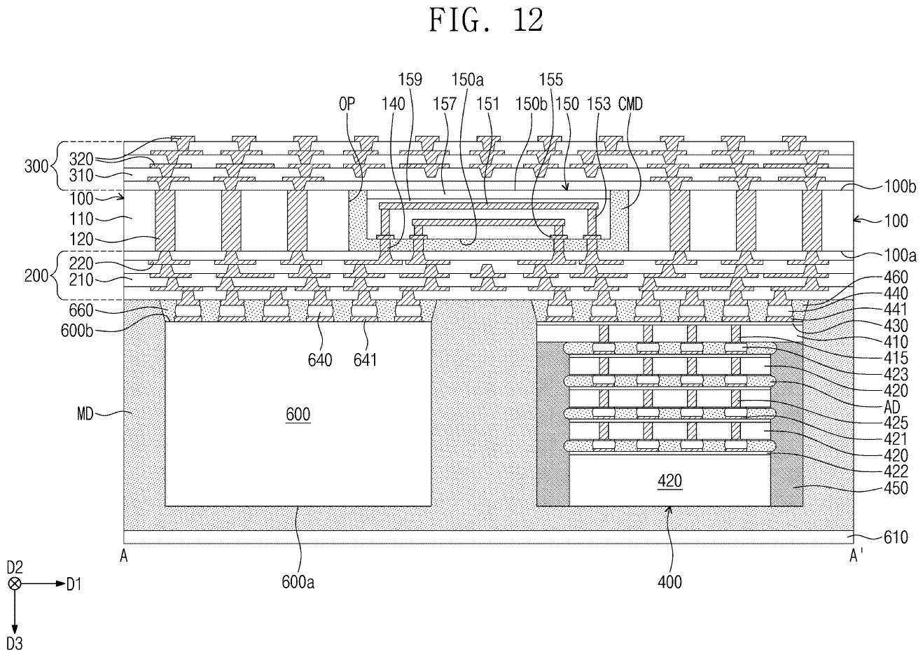

Referring to FIG. 12, the second carrier substrate CF2 may be removed. The removal of the second carrier substrate CF2 may expose the dielectric film 610.

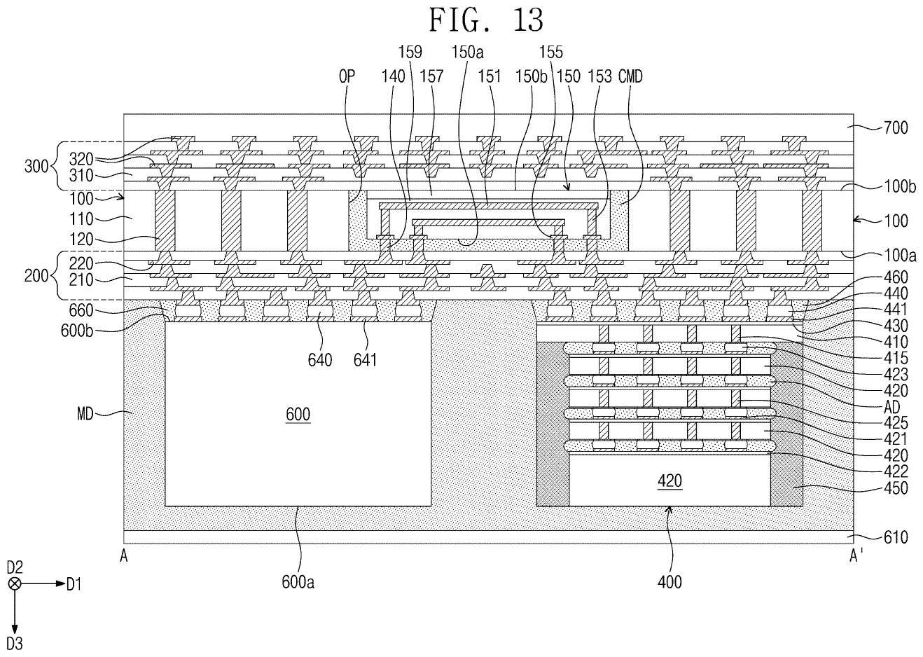

Referring to FIG. 13, a photoresist film 700 may be formed on the second redistribution substrate 300. The photoresist film 700 may include, for example, a dry film resist (DFR).

An exposure process may be performed on the photoresist film 700. The photoresist film 700 may then be cured. In this case, the cured photoresist film 700 may protect the second redistribution substrate 300. For example, when the second redistribution substrate 300 is loaded on a chuck of a certain apparatus, the second redistribution substrate 300 may be protected by the cured photoresist film 700.

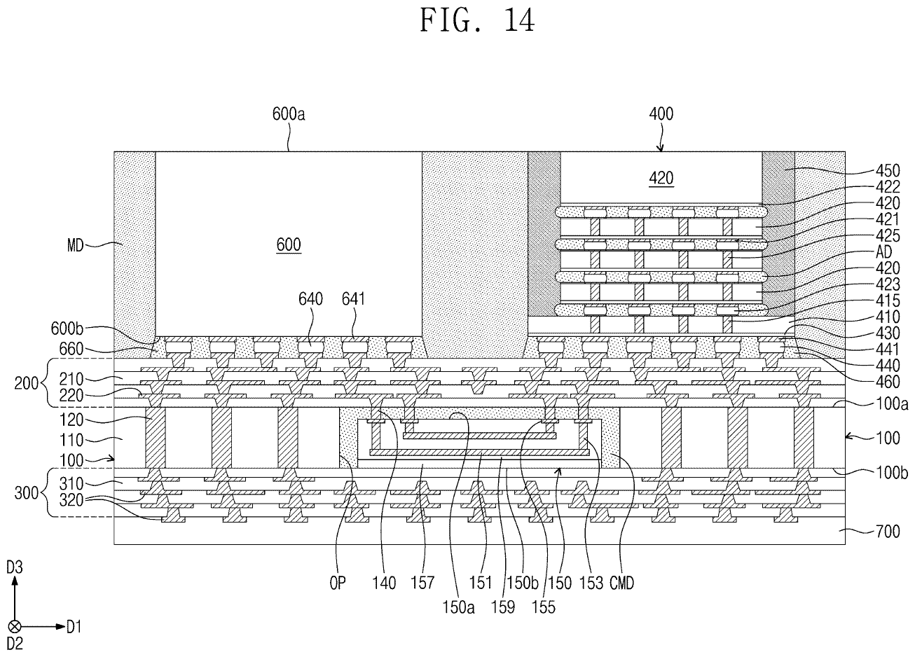

Referring to FIG. 14, the photoresist film 700 may be overturned to allow the first surface 600a of the base chip 600 to face upwards. For example, a semiconductor package being fabricated may be turned upside down. Therefore, the photoresist film 700 may be positioned at a lower location.

A planarization process may be performed on the mold layer MD. The planarization process may include a chemical mechanical polishing (CMP) process. According to some embodiments, the planarization process may continue until the first surface 600a of the base chip 600 is exposed. According to some embodiments, the planarization process may partially remove upper portions of the base chip 600 and the unit chip package 400.

Referring back to FIG. 2A, the photoresist film 700 may be removed. Afterwards, redistribution connection terminals 350 may be connected to corresponding second redistribution patterns 320.

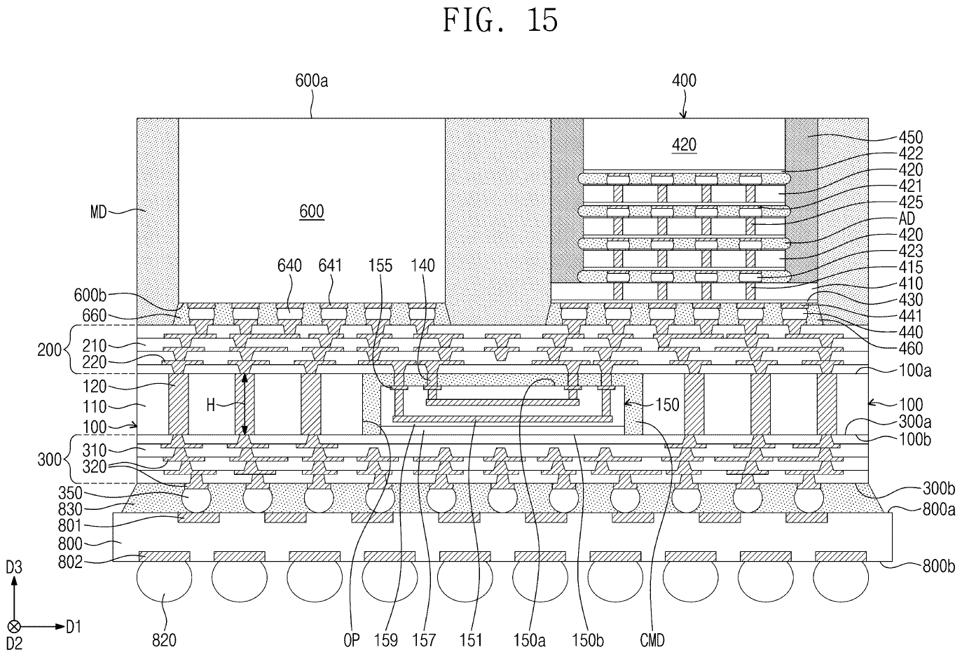

FIG. 15 illustrates a cross-sectional view showing a semiconductor package according to some embodiments of the present inventive concepts. For brevity of description, a repetitive explanation will be omitted.

Referring to FIG. 15, a semiconductor package according to some embodiments of the present inventive concepts may include a package substrate 800, a first redistribution substrate 200, a second redistribution substrate 300, a via structure 100, a bridge chip 150, and chip structures 400 and 600. The chip structures 400 and 600 may include, for example, a unit chip package 400 and a base chip 600. The package substrate 800 may have a first surface 800a and a second surface 800b that are opposite to each other in a third direction D3. In the description of FIG. 15, a first direction D1 and a second direction D2 may be directions that are parallel to the first surface 800a of the package substrate 800 and are crossed (i.e., transverse) to each other. The third direction D3 may be a direction perpendicular to the first surface 800a of the package substrate 800. The third direction D3 may be called a vertical direction. For example, the first, second, and third directions D1, D2, and D3 may intersect each other.

Lower chip pads 802 may be disposed on the second surface 800b of the package substrate 800. The lower chip pads 802 may be electrically connected to a circuit layer (not shown) in the package substrate 800. External connection terminals 820 may be correspondingly disposed on and connected to the lower chip pads 802. The external connection terminals 820 may be electrically connected through the lower chip pads 802 to the package substrate 800. The external connection terminals 820 may include solder balls or solder bumps. The external connection terminals 820 may each be an alloy that includes one or more of the following: tin (Sn), silver (Ag), copper (Cu), nickel (Ni), bismuth (Bi), indium (In), antimony (Sb), and cerium (Ce).

Upper chip pads 801 may be disposed on an upper portion of the package substrate 800. The upper chip pads 801 may have top surfaces that are exposed without being covered with the package substrate 800. The upper chip pads 801 may be electrically connected to a circuit layer (not shown) in the package substrate 800.

The upper chip pads 801 and the lower chip pads 802 may include copper (e.g., copper).

The package substrate 800 may be provided thereon with the semiconductor package 10 discussed with reference to FIGS. 1 and 2A to 2D. An underfill layer 830 may be interposed between the semiconductor package 10 and the package substrate 800. The underfill layer 830 may cover a lateral surface of each of the redistribution connection terminals 350. For example, the underfill layer 830 may fill a space between the redistribution connection terminals 350. The underfill layer 830 may include a dielectric polymer material, such as epoxy resin.

A semiconductor package according to the present inventive concepts may utilize a via structure that is manufactured to have a symmetric interval between conductive posts. Thus, it may not be required to perform a planarization process on the conductive posts, and it may be possible to eliminate the risk of increased variation in heights of the conductive posts.

Additionally, there may be no occurrence of failure where a photoresist remains on the conductive posts. Furthermore, it may be possible to prevent the occurrence of wafer warpage. In conclusion, the semiconductor package may improve in reliability and electrical properties.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts.

What is claimed is

1. A method of fabricating a semiconductor package, the method comprising:
attaching a first surface of a via structure to a surface of an adhesive member, the via structure comprising an opening;
forming a plurality of conductive connectors and a bridge chip on the surface of the adhesive member and in the opening of the via structure;
removing the adhesive member;
forming a first redistribution substrate on the first surface of the via structure;
mounting a plurality of chip structures on the first redistribution substrate; and
forming a second redistribution substrate on an opposite second surface of the via structure,
wherein the bridge chip has a first surface and an opposite second surface, and
wherein the first surface of the bridge chip and the first surface of the via structure are located at respective different levels.

2. The method of claim 1, wherein the via structure comprises:
a via base layer; and
a plurality of conductive posts extending through the via base layer.

3. The method of claim 2, wherein the via base layer comprises at least one selected from silicon, glass, or organics.

4. The method of claim 2, wherein the organics comprise at least one selected from fiber glass epoxy, glass paper epoxy, Teflon™, resin coated copper (RCC), or ceramics.

5. The method of claim 2, wherein
a variation in heights of the plurality of conductive posts is less than about 10 μm.

6. The method of claim 5, wherein the heights of the plurality of conductive posts are about 100 to 250 μm.

7. The method of claim 2, wherein the plurality of conductive posts are spaced apart from each other in a first direction and a second direction that are parallel to the first surface of the via structure, wherein the first direction and the second direction are transverse to each other,
wherein a first distance in the first direction between conductive posts that neighbor each other in the first direction is about 0.8 to 1.2 times a diameter of the conductive posts.

8. The method of claim 7, wherein a second distance in the second direction between conductive posts that neighbor each other in the second direction is about 0.8 to 1.2 times the diameter of the conductive posts.

9. The method of claim 1, further comprising, after the forming the plurality of conductive connectors and the bridge chip, forming a bridge mold layer on the surface of the adhesive member and in the opening of the via structure, the bridge mold layer covering the plurality of conductive connectors and the bridge chip.

10. The method of claim 1, further comprising, after the forming the plurality of conductive connectors and the bridge chip, and before the removing the adhesive member, forming a first carrier substrate on the second surface of the via structure.

11. The method of claim 1, wherein the plurality of chip structures comprise a base chip and a unit chip package that are spaced apart from each other in a direction parallel to the first surface of the via structure.

12. The method of claim 1, further comprising, after mounting the plurality of chip structures on the first redistribution substrate, forming on the first redistribution substrate a mold layer that covers the plurality of chip structures.

13. A method of fabricating a semiconductor package, the method comprising:
attaching a first surface of a via structure to a surface of an adhesive member, the via structure comprising an opening;
forming a plurality of conductive connectors and a bridge chip on the surface of the adhesive member and in the opening of the via structure;
forming a first carrier substrate on an opposite second surface of the via structure;
removing the adhesive member;
forming a first redistribution substrate on the first surface of the via structure;
mounting a plurality of chip structures on the first redistribution substrate;
forming on the first redistribution substrate a mold layer that covers the plurality of chip structures;
removing the first carrier substrate;
forming a second carrier substrate on the mold layer; and
forming a second redistribution substrate on the second surface of the via structure,
wherein the bridge chip has a first surface and an opposite second surface, and
wherein the first surface of the bridge chip and the first surface of the via structure are located at respective different levels.

14. The method of claim 13, wherein the via structure comprises:
a via base layer; and
a plurality of conductive posts extending within the via base layer,
wherein the plurality of conductive posts are spaced apart from each other in a first direction and a second direction that are parallel to the first surface of the via structure, wherein the first direction and the second direction are transverse to each other.

15. The method of claim 14, wherein a variation in heights of the plurality of conductive posts is less than about 10 μm.

16. The method of claim 14, wherein
the plurality of conductive posts have a cylindrical shape with a diameter of about 40 to 100 μm.

17. The method of claim 13, wherein the plurality of chip structures comprise a base chip and a unit chip package that are spaced apart from each other in a direction parallel to the first surface of the via structure.

18. The method of claim 13, further comprising a bridge mold layer on the surface of the adhesive member and in the opening of the via structure, the bridge mold layer covering the plurality of conductive connectors and the bridge chip.

19. The method of claim 13, further comprising, after the forming the second redistribution substrate,
removing the second carrier substrate;
forming a photoresist film on the second redistribution substrate; and
planarizing the mold layer to expose surfaces of the plurality of chip structures.

20. A method of manufacturing a semiconductor package, the method comprising:
attaching a first surface of a via structure to a surface of an adhesive member, wherein the via structure comprises a base layer, a plurality of conductive posts extending through the base layer, and an opening;
forming a plurality of conductive connectors and a bridge chip on the surface of the adhesive member and in the opening of the via structure;
forming a bridge mold layer on the surface of the adhesive member and in the opening of the via structure, the bridge mold layer covering the plurality of conductive connectors and the bridge chip;
removing the adhesive member;
forming a first redistribution substrate on the first surface of the via structure;
mounting a plurality of chip structures on the first redistribution substrate; and
forming a second redistribution substrate on an opposite second surface of the via structure.
